(19) United States
(12) Patent Application Publication
(10) Pub. No.: US 2025/0391811 A1
(43) Pub. Date: Dec. 25, 2025

(54) UTILIZING FORMATE SHELLS FOR METAL STRUCTURES ON INTEGRATED CIRCUIT COMPONENTS

(71) Applicant: INTERNATIONAL BUSINESS MACHINES CORPORATION, ARMONK, NY (US)

(72) Inventors: CHARLES LEON ARVIN, POUGHKEEPSIE, NY (US); STEVEN PAUL OSTRANDER, POUGHKEEPSIE, NY (US); BHUPENDER SINGH, FISHKILL, NY (US); VALÉRIE ANNE OBERSON, ST-ALPHONSE-DE-GRANBY (CA)

(21) Appl. No.: 18/750,129

(22) Filed: Jun. 21, 2024

(51) Int. Cl. H01L 23/00

(52) U.S. Cl. CPC H01L 24/81; H01L 24/13; H01L 24/16; H01L 24/75; H01L 2224/13561; H01L 2224/136; H01L 2224/13687; H01L 2224/16505; H01L 2224/75101; H01L 2224/81009; H01L 2224/81948

(57) ABSTRACT

Aspects of utilizing formate shells for metal structures on integrated circuit components include an integrated circuit device component including one or more metal interconnect structures and a formate shell on each of the one or more metal interconnect structures.

### BACKGROUND

The present disclosure relates to methods, apparatus, and products for utilizing formate shells for metal structures on integrated circuit components.

### SUMMARY

According to embodiments of the present disclosure, various methods, apparatus and products for utilizing formate shells for metal structures on integrated circuit components are described herein. In some aspects, utilizing formate shells for metal structures on integrated circuit components includes providing an integrated circuit device component including one or more metal interconnect structures and forming a formate shell on the one or more metal interconnect structures of the integrated circuit device component, where the formate shell is stable. The formate shell prevents oxidation or further oxidation of the metal. During a thermal process, such as solder reflow, decomposition of the formate shell due to the application of heat removes any oxide layer on the metal. The reducing effect of formic acid is achieved without the need for formic acid handling at the point of thermal processing.

### BRIEF DESCRIPTION OF THE DRAWINGS

FIG. 1A depicts a cross-section of an example integrated circuit device component including a metal formate shell in accordance with at least one embodiment of the present disclosure.

FIG. 1B depicts a cross-section of another example of the integrated circuit device component in accordance with at least one embodiment of the present disclosure.

FIG. 2A sets forth a sectional view of a joining of two components having a formate shell in accordance with at least one embodiment of the present disclosure.

FIG. 2B sets forth another view of the joining of two components having a formate shell shown in FIG. 2A.

FIG. 3 sets forth a flow chart of an example method of utilizing formate shells for metal structures on integrated circuit components in accordance with at least one embodiment of the present disclosure.

FIG. 4 sets forth a flow chart of another example method of utilizing formate shells for metal structures on integrated circuit components in accordance with at least one embodiment of the present disclosure.

FIG. 5 sets forth a flow chart of another example method of utilizing formate shells for metal structures on integrated circuit components in accordance with at least one embodiment of the present disclosure.

FIG. 6 sets forth a flow chart of another example method of utilizing formate shells for metal structures on integrated circuit components in accordance with at least one embodiment of the present disclosure.

FIG. 7 sets forth a flow chart of another example method of utilizing formate shells for metal structures on integrated circuit components in accordance with at least one embodiment of the present disclosure.

FIG. 8 sets forth a flow chart of another example method of utilizing formate shells for metal structures on integrated circuit components in accordance with at least one embodiment of the present disclosure.

FIG. 9 sets forth a flow chart of another example method of utilizing formate shells for metal structures on integrated circuit components in accordance with at least one embodiment of the present disclosure.

### DETAILED DESCRIPTION

In assembling and constructing an integrated circuit device, such as a semiconductor package, metallurgical bonds are formed between various integrated circuit device components. Advanced packaging techniques integrate many heterogenous components in a single package. For example, a semiconductor die may be bonded to another die or a substrate in fabricating a semiconductor package, other dies may be added to that same substrate, various surface mount technology (SMT) devices may also be bonded to the substrate, the semiconductor package may be bonded to a printed circuit board (PCB), and so on. Common bonding techniques for joining integrated circuit device components include solder reflow, thermal compression bonding, hybrid bonding, and the like. The metallurgical bonds of the components are established between metal interconnect structures on each component, such as solder structures or pillars on one component and solder pads or bond pads on another component. These metal interconnect structures are commonly formed of copper, tin, nickel, gold, and various alloys of the same.

Metal oxides form naturally on the surface of metals when they are exposed to oxygen rich environments such as air. These metal oxides can act as a barrier that prevents a proper metallurgical bond between interconnects. For example, metal oxides can prevent solder from properly wetting. Poor wetting results in weak joints, which can lead to mechanical and electrical failures. Further, metal oxides are relatively poor conductors of electricity compared to the metal in its non-oxidized state. Oxides that are present at the bond sites can interfere with the electrical connection, leading to high resistance or intermittent connections. Still further, oxides can lead to brittle solder joints that are more susceptible to mechanical stress and thermal cycling, which can lead to a complete failure of the joint over time.

It is therefore important that oxides be removed from the surfaces of the metal interconnect structures prior to metallurgical bond formation. Various techniques have been proven effective at reducing the oxides on metal surfaces of integrated circuit device components; however, each has its own drawbacks and limited application. On technique applies a flux that dissolves the various metal oxides from the surface. Two common varieties are a water-soluble flux and a no clean flux, both of which pose problems in advanced packaging related to high-pressure spray that can remove small sensitive components or residual materials that interfere with subsequent assembly materials (e.g. underfill adhesion). These materials also incorporate materials or require water wash that can be detrimental to components such as optics and photonics. For example, optics cannot be exposed to water wash and the no clean flux creates issues with underfill adhesion. Further, many in the industry are moving toward thermal compression bonding (TCB) as the preferred chip join method. However, the smaller interconnect pitches are leading to issues with the flux water wash when small pitch items, such as a high bandwidth memory (HBM) device are on the same laminate as a large CPU die. The requisite high-pressure water wash to remove the flux can knock the HBM device off of the laminate.

Despite these drawbacks, flux provides the advantage of reducing the oxide on the metal by its presence during the reflow or TCB process, whereas other approaches have attempted to reduce the oxide in a standalone tool and transport the component to the bonding tool (e.g., reflow furnace or TCB tool). Oxides begin forming within seconds, even under vacuum conditions, which has not made the removal of oxides prior to the bonding processes conducive for the multiple steps required for semiconductor packaging.

Formic acid is effective at reducing metal oxides in semiconductor applications and is safe for use with optics and other applications that are not amenable to the washing needed when flux is used. Like flux, formic acid will reduce the metal oxides when heated and is thus reactive during the thermal processes associated with bonding. Unlike flux, there is no need to wash the components, as the redox reaction converts the formic acid and oxide to water and carbon dioxide, leaving only metal surface on the interconnects. However, to be effective, the formic acid must be present during the bonding process and within the bonding tool. As such, the bonding tool (e.g., reflow furnace or TCB tool) must be adapted to handle formic acid. This can include putting hardware mechanisms in place to prevent human exposure, as well as managing the diffusion constraints against introducing formic acid into the reflow furnace. Further, to enable a formic acid reflow furnace, a specialized tool set would be required that pulls a vacuum to enable transport of the formic acid under the die. In other words, the adaption of bonding tools to provide safe handling of formic acid for use in reducing oxides during the bonding process is expensive and complex.

In addition to its ill effects on bonding, oxidation also poses supply chain problems. Recent shortages of integrated circuit device components have driven to demand to maintain stockpiles of these components. However, component manufacturers typically advise the components should not be stored for more than two years. Therefore, mechanisms to prolong the shelf life of such components are advantageous.

Embodiments in accordance with the present disclosure provide a formate shell on metal interconnect structures of integrate circuit device components. In some examples, the formate shell results from a chemical bond of the formate molecule to a metal oxide that does not reduce the oxide. Where metal oxide is not present, the formate shell results from a chemical bond of the formate molecule to the metal. These are stable bonds and do not create an exposed metal surface that can react with oxygen during storage or transport. In subsequent bonding processes, when the formate shell is exposed to the thermal processes of bonding, the formate shell will reduce any oxide layers that are present on the metal interconnects. Decomposition of the formate shell does not yield any formic gas. Thus, the bonding tool does not require special adaptation to handle formic gas or safeguard against human exposure to it. Further, because the formate shell is stable and prevents oxidation, the formate shell can be used to extend the shelf-life of these components.

In a particular example, the metal formate shell is created on the metal surfaces of individual components, such as dies, laminates, sockets, modules, connectors, sub-assembly components, wafers, etc. The metal surfaces will retain their metal oxide, if present, but have a metal oxide formate formed on the surface. As there is no exposed metal surface, the formate shell prevents oxidation or further oxidation of the metal. The creation of the formate shell is carried out as a separate process and need not be incorporated into any bond tool. Components having the formate shell can be placed in storage for later use or can be transported to the bonding tool without risk of oxidation in between.

During bonding, the component having the formate shell can be placed in a standard tool set such as reflow or TCB tool with the metal formate enabling full removal of oxides during the thermal processes without the need for flux. In this way, it is possible to utilize existing manufacturing equipment that does not have formic acid capability while delivering the benefits of oxide removal via the formate molecule.

In a particular example, a fixture is provided that can pull a vacuum on a chamber enclosing the integrated circuit device component and backfill the chamber with formic acid gas. The fixture is heated to between 130° C. and 180° C., thereby adding the formate shell to the surfaces of exposed metals. The fixture can be heated in a box oven or even a belt furnace with a peak/dwell at 130° C. to 180° C. depending upon the exposed metal. The fixture can then be evacuated and back filled with nitrogen gas to prevent the release of formic acid. After removal and backfilling with nitrogen, the same fixture can be sent through a standard belt furnace so to obviate removal of the components from the fixture but also to avoid any concern of contamination from the components into the furnace.

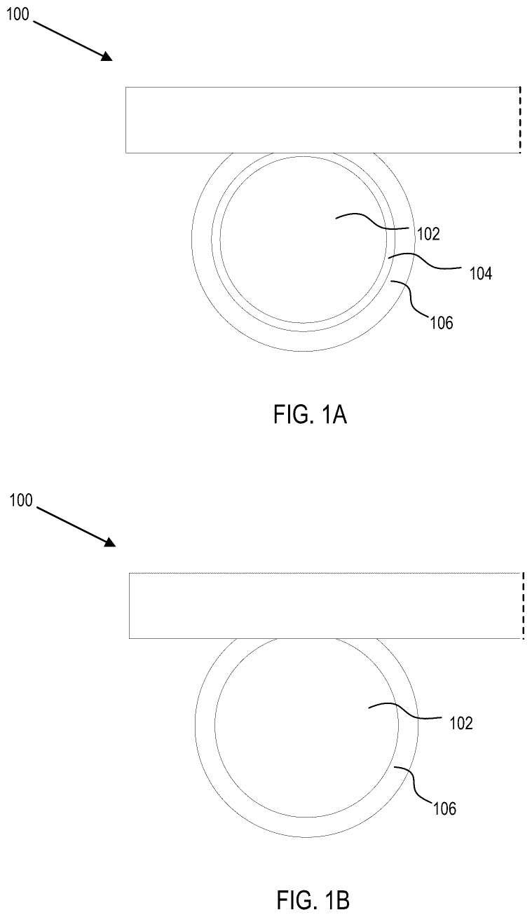

FIG. 1A depicts a cross-section of an example integrated circuit device component including a metal formate shell in accordance with at least one embodiment of the present disclosure. In the example of FIG. 1A, integrated circuit device component 100 is a semiconductor die. However, a semiconductor die is shown for illustrative purposes only. In other examples, the integrated circuit device component 100 can be other types of discrete integrated circuit components that are joined together in assembling an integrated circuit device. For example, the integrated circuit device component 100 can be a wafer, semiconductor module, surface mount technology (SMT) device (e.g., a chip capacitor), connector (e.g., a fiber optic connector), laminate or substrate, interposer, socket, printed circuit board (PCB), and the like. In a particular example, the integrated circuit device component 100 is a component that will be joined with another integrated circuit device component during a reflow process, thermal compression bonding (TCB) process, hybrid bonding process, or other thermal joining process.

For example, the integrated circuit device component 100 may be mounted with another component and joined in a reflow furnace or TCB tool.

The integrated circuit device component 100 includes an array of metal interconnect structures 102. In the example of FIG. 1A, the metal interconnect structures 102 are solder structures (e.g., solder balls or microbumps in a ball grid array). However, solder structures are shown for illustrative purposes only. In other examples, the metal structures can be other types of conductive metal structures that establish an electrical connection between two integrated circuit device components. For example, the metal interconnect structures can be pillars, pins, leads, solder paste, solder pads, bond pads, and the like. In various examples, the metal interconnect structures 102 are composed of copper, tin, nickel, or gold.

As shown in FIG. 1A, the metal interconnect structures 102 include an oxide layer 104. The presence of the oxide layer 104 may be due to oxidation via exposure to an oxygen rich environment (e.g., air). For example, as a result of dangling bonds at the faces of the crystalline lattice of the metal composition, the surface metal of the metal interconnect structures 102 can include copper (I) ions having an oxidation state of +1, copper (II) ions having an oxidation state of +2, tin (II) ions having an oxidation state of +2, tin (IV) ions having an oxidation state of +4, nickel (II) ions having an oxidation state of +2, or gold (III) ions having an oxidation state of +3. The oxidation layer 104 forms when oxygen molecule reacts with the metal cations.

As discussed above, oxidation of the metal of the metal interconnect structures 102 has deleterious effects on the joining of two integrated circuit device components. To address, this, the metal interconnect structures 102 also include a formate shell 106. The formate shell 106 is the result of an adsorption of the formate molecule (HCOO⁻) onto the metal oxide layer 104, as will be discussed in greater detail below. As such, in the example of FIG. 1A, the formate shell 106 is a metal oxide formate shell. For example, where the metal interconnect structures 102 are composed of copper, the formate shell 106 may be cuprous oxide formate. The formate shell 106 is formed on the exposed surface of the metal of the metal interconnect structures 102. The formate shell 106 prevents further oxidation of the metal interconnect structures 102. When the integrated circuit device component 100 is heated during a join process, such as a reflow or TCB process, the formate shell 106 decomposes (e.g., in a temperature range of 180° C. to 230° C.). When the formate shell 106 decomposes, the oxide layer 104 is removed from the metal interconnect structures 102 as the formate shell 106 and oxide layer 104 are converted to carbon dioxide and water, leaving the surface of the metal interconnect structures 102 wetted for joining with another component.

FIG. 1B depicts a cross-section of another example of the integrated circuit device component 100 in accordance with at least one embodiment of the present disclosure. The example of FIG. 1B differs from the example of FIG. 1A in that an oxide layer is not present. For example, as will be explained in greater detail below, the oxide layer may have been removed prior to formation of the formate shell. In the example of FIG. 1B, the formate molecule is adsorbed directly onto the metal cations at the surface of the metal interconnect structures 102. The formate shell 106 prevents oxidation of the metal interconnect structures 102. When the integrated circuit device component 100 is heated during a join process, such as a reflow or TCB process, the formate shell 106 decomposes (e.g., in a temperature range of 180° C. to 230° C.). When the formate shell 106 is converted to carbon dioxide and water upon decomposition, leaving the surface of the metal interconnect structures 102 wetted for joining with another component.

Thus, it will be appreciated that a formate shell 106 in accordance with FIG. 1A or FIG. 1B protects the metal interconnect structures 102 of an integrated circuit device component 100 from oxidation, thus permitting the integrated circuit device component 100 to be stored for long periods of time, or to be transported from one processing point to another, without adversely affecting a future electrical connection of the integrated circuit device component 100 to another component. Further, when the integrated circuit device component 100 is eventually joined with another component, decomposition of the formate shell 106 due to heating will remove any oxidation present on the metal interconnect structures 102. Thus, oxidation removal via the formate reaction is fluxless and can be carried out in conventional tooling such as a reflow furnace or TCB tool without special adaptation or safeguards for utilizing formic acid gas.

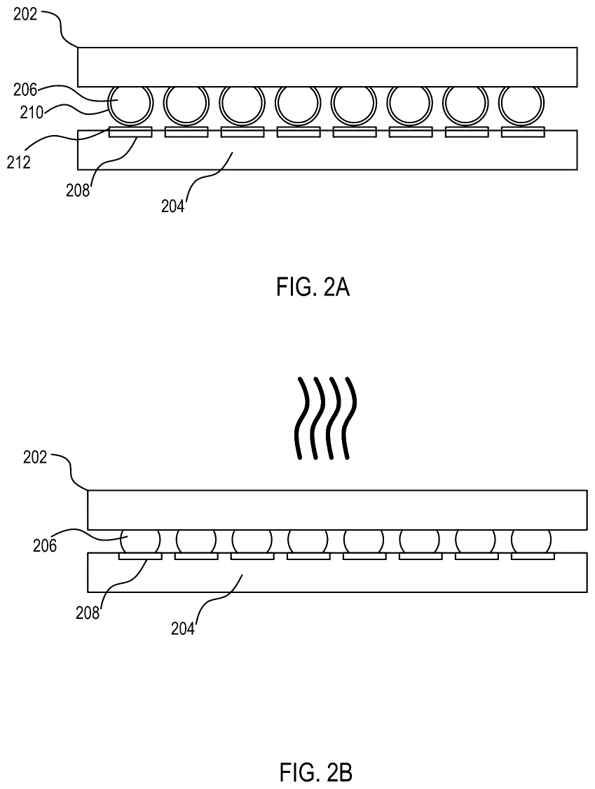

For further explanation, FIGS. 2A and 2B set forth a sectional view of a joining of two components having a formate shell in accordance with at least one embodiment of the present disclosure. In FIG. 2A, a first component 202 is mounted on a second component 204. Components 202, 204 may be integrated circuit device components that are electrically and mechanically joined in assembling the integrated circuit device. For purposes of illustration, consider that the first component 202 is a semiconductor die and that the second component 204 is a substrate, as shown. The first component 202 includes metal interconnect structures 206 in the form of solder structures, while the second component 204 includes metal interconnect structures 208 in the form of solder pads. The metal interconnect structures 206, 208 include respective formate shells 210, 212.

In FIG. 2B, a solder reflow process is carried out on the first component 202 and the second component 204. As the components are heated to a temperature range of 180° C. to 230° C., the formate shells 210, 212 decompose and remove any oxide layers that are present on the metal interconnect structures. As the temperature increases further, solder reflow establishes a mechanical and electrical connection between the components 202, 204. Here, oxidation removal via the formate reaction is fluxless and can be carried out in conventional tooling such as a reflow furnace or TCB tool without special adaptation or safeguards for utilizing formic acid gas. Further, creation of the formate shell on each component can be carried out far in advance of the join process of the two components, thus facilitating multistep semiconductor packaging processes and storage of integrated circuit components prior to use.

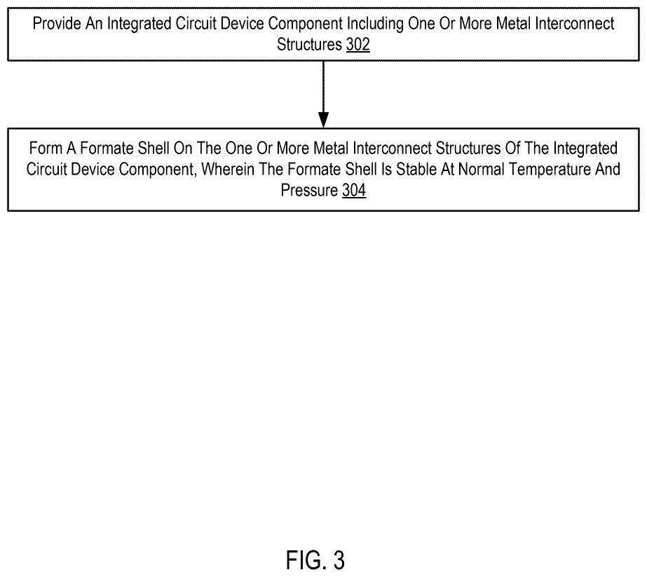

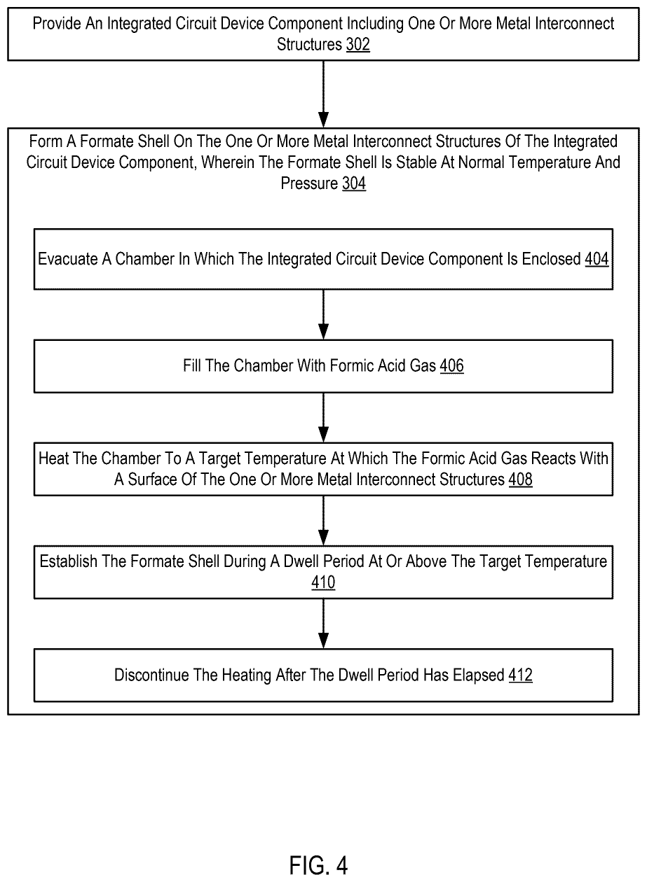

For further explanation, FIG. 4 sets forth a flow chart of an example method for utilizing formate shells for metal structures on integrated circuit components. Specifically, FIG. 4 pertains to creating the formate shell on the metal interconnect structures of an integrated circuit device component. The method of FIG. 3 includes providing 302 an integrated circuit device component including one or more metal interconnect structures. In some examples, the integrated circuit device component is in accordance with the integrated circuit device component discussed above with reference to FIGS. 1A and 1B. In various examples, the integrated circuit device component can be a semiconductor die, wafer, semiconductor module, SMT device, connector, laminate or substrate, interposer, socket, or PCB.

In preparation for creating the formate shell, the integrated circuit device component is placed in a chamber having one or more gas ports for gas fill and evacuation. In some implementations, the chamber is part of or coupled to a fixture that holds one or more integrated circuit device components. For example, the fixture and chamber may be configured to hold a JEDEC tray. In such an example, the integrated circuit device component is placed in a JEDEC tray, which is then placed in the chamber. In another example, a tacky film applied to a floor of the chamber can be used to hold the integrated circuit device component in place. In some implementations, the fixture is configured to be received within a conventional belt furnace, box furnace, or TCB tool. While the following examples discuss a single integrated circuit device component, it will be appreciated that the chamber may enclose multiple integrated circuit devices. In some examples, one integrated circuit device component can be mounted on another integrated circuit device component in preparation for a reflow process, TCB process, or other joining process.

The method of FIG. 3 also includes forming 304 a formate shell on the one or more metal interconnect structures of the integrated circuit device component, wherein the formate shell is stable at normal temperature and pressure. In various examples, forming 304 a formate shell on one or more metal interconnect structures of an integrated circuit device component includes forming 304 the formate shell on one or more of controlled collapse chip connection (C4) balls, microbumps, or other solder structures, pillars, pins, leads, solder paste, solder pads, or bond pads of the integrated circuit device component. In some examples, forming 304 the formate shell on the one or more metal interconnect structures of the integrated circuit device component is carried out using formic acid gas to create a chemisorption bond between formate molecules and the metal or metal oxide layer of the metal interconnect structures. In some implementations, as will be discussed in more detail below, the formate shell is established by filling the chamber with formic acid gas and heating the chamber to a temperature at which the formate shell forms without exceeding a temperature at which the formic shell decomposes. The resulting formate shell is established over all exposed areas of metal or metal oxide. Further, the formate shell is stable at normal temperature and pressure, identified herein as 20° C. and 1 atmosphere of pressure using the definition of the National Institute of Standards and Technology (NIST). Accordingly, the integrated circuit device component is prepared for exposure to air during storage or transport without risk of oxidation or further oxidation of the metal interconnect structures due to the formate shell. Further, the formate shell facilitates the reduction of oxide layers during later thermal processing without special tooling adapted to diffuse formic acid gas, as decomposition of the format yields water and carbon dioxide.

For further explanation, FIG. 4 sets forth another example method of utilizing formate shells for metal structures on integrated circuit components in accordance with at least one embodiment of the present disclosure. The method of FIG. 4 extends the method of FIG. 3 in that forming 304 the formate shell on the one or more metal interconnect structures of the integrated circuit device component includes evacuating 404 a chamber in which the integrated circuit device component is enclosed, filling 406 the chamber with formic acid gas, heating 408 the chamber to a target temperature at which the formic acid gas reacts with a surface of the one or more metal interconnect structures, establishing 410 the formate shell during a dwell period at or above the target temperature, and discontinuing 412 the heating after the dwell period has elapsed.

In some examples, evacuating 404 a chamber in which the integrated circuit device component is enclosed is carried out by pulling a vacuum on the chamber via the gas port such that all air in the chamber is evacuated. A conventional vacuum pump can be used, and one or more sensors can be used to monitor pressure and/or gas content within the chamber.

In some examples, filling 406 the chamber with formic acid gas is carried out by pumping a mixture of nitrogen and formic acid (CH₂O₂, having a structure H—C—O—O—H) into the chamber via the gas port. In a particular implementation, the resulting gas pumped into the chamber is approximately 5% saturated with formic acid.

In some examples, heating 408 the chamber to a target temperature at which the formic acid gas reacts with a surface of the one or more metal interconnect structures is carried out by heating the fixture in a conventional box oven or belt furnace and controlling the heat applied to the fixture. The heat applied can be compensated for the mass of the fixture. During a ramp up period, the temperature within the chamber is increased to a target temperature at which the formic acid gas will react with the metal or metal oxide of the metal interconnect structures. In various implementations, the target temperature may be within a range of 130° C. to 180° C.; however, it will be appreciated that the target temperature for creation of the formate shell will depend on the type of metal of the metal interconnect. For example, the target temperature for creating the formate shell on nickel interconnect structures may be approximately 130-140° C., whereas the target temperature for creating the formate shell on nickel interconnect structures may be 170-180° C. Identification of the appropriate target temperature based on properties of the metal is within the capability of the ordinarily skilled technician. Once the target temperature is reached, the formic acid will begin absorbing onto the metal or metal oxide of the metal interconnect structures.

In some examples, establishing 410 the formate shell during a dwell period at or above the target temperature is carried out by maintaining the temperature within the chamber at or above the target temperature but below a maximum peak temperature at which reduction of any oxide layer on the metal interconnect structures would occur and/or decomposition of the formate shell would occur. It will be appreciated that the maximum peak temperature at which reduction of any oxide layer on the metal interconnect structures would occur depends on the type of metal and can be determined from physical chemistry reference materials. The dwell period is an amount of time during which the formic acid absorbs onto the metal interconnect structures via a chemisorption bond, thus established the formate shell that completely covers any exposed metal of the metal interconnect structures. For example, the dwell period may be on the order of minutes.

In some examples, discontinuing 412 the heating after the dwell period has elapsed is carried out by removing the fixture from the oven or furnace, or by discontinuing the heat applied by the oven or furnace. In contrast to techniques that use a special formic acid reflow tool, where heating of the components continues until the oxide is reduced and reflow occurs, techniques in accordance with the present disclosure discontinue heating of the integrated circuit device component once the formate shell has been established during the dwell period. After the dwell period is over, the heating is discontinued and the component can be removed from the fixture after removal or dissipation of the remaining formic acid gas within the chamber. Alternatively, the formic acid gas can be evacuated, thus conditioning the fixture for transport to a reflow oven, TCB tool, or other bonding facility. The resulting formate shell is stable, and the integrated circuit device component is prepared for exposure to air during storage or transport without risk of oxidation or further oxidation of the metal interconnect structures.

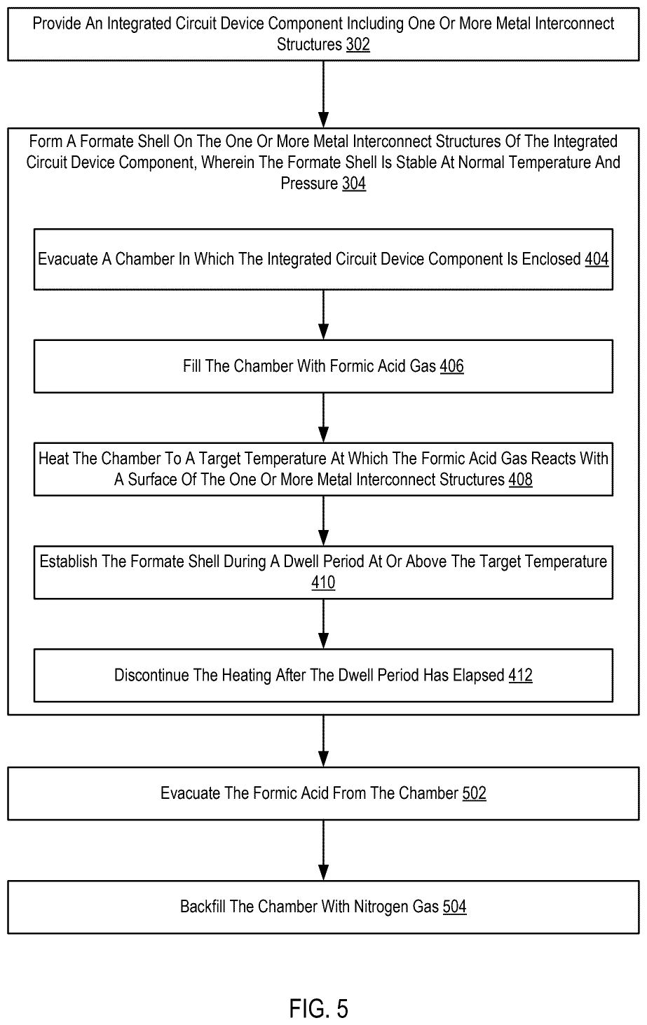

For further explanation, FIG. 5 sets forth another example method for utilizing formate shells for metal structures on integrated circuit components. The example of FIG. 5 extends the method of FIG. 3 in that the method of FIG. 5 also includes evacuating 502 the formic acid from the chamber. In some examples, evacuating the formic acid from the chamber is carried out by pulling a vacuum on the chamber via the gas port through which the remaining formic acid gas is evacuated from the chamber. That is, any formic acid gas that is not adsorbed onto the metal interconnect structures is drawn out of the chamber.

The method of FIG. 5 also includes backfilling 504 the chamber with nitrogen gas. In some examples, backfilling 504 the chamber with nitrogen gas is carried out by pumping nitrogen gas into the chamber via the gas port until the pressure in the chamber is approximately 1 atmosphere. In this way, the fixture can be relocated to a reflow tool, TCB tool, or other bonding tool that is not specifically adapted for diffusing formic acid gas. In other words, the nitrogen-only atmosphere within the chamber makes the fixture suitable for use in a conventional reflow furnace or TCB tool.

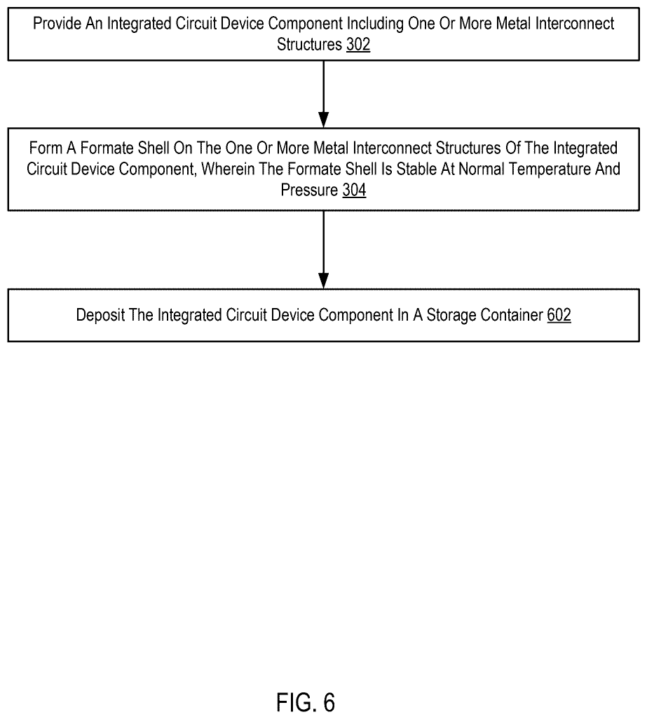

For further explanation, FIG. 6 sets forth another example method for utilizing formate shells for metal structures on integrated circuit components. The example of FIG. 6 extends the method of FIG. 3 in that the method of FIG. 6 also includes depositing 602 the integrated circuit device having the formate shell in a storage container. As earlier discussed, the formate shell is stable on the metal interconnect structures of the integrated circuit device component and serves to protect the metal interconnects from oxidation or further oxidation. As such, the integrated circuit component with the formate shell is suited for storage. In some examples, depositing 602 the integrated circuit device component having the formate shell in a storage container is carried out by placing the integrated circuit device component including the metal interconnect structures with the formate shell in an electrostatic bag or other container. In this way, a supply of the integrated circuit device components can be maintained for later use in assembling the integrated circuit device.

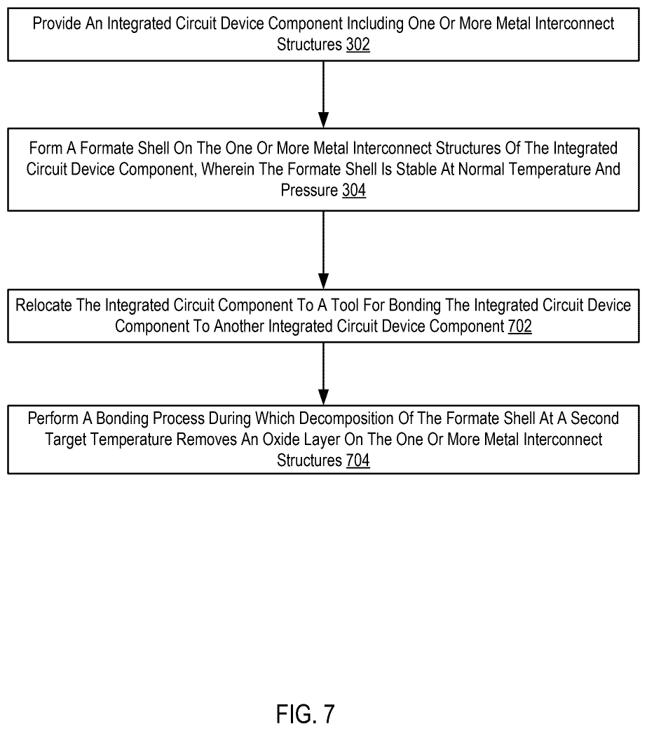

For further explanation, FIG. 7 sets forth another example method for utilizing formate shells for metal structures on integrated circuit components. The example of FIG. 7 extends the method of FIG. 3 in that the method of FIG. 7 also includes relocating 702 the integrated circuit component to a tool for bonding the integrated circuit device component to another integrated circuit device component. As mentioned above, an advantage of the fixture is that it provides a formic acid furnace that is separate from the tooling (e.g., reflow or TCB tooling) used for joining integrated circuit device component to other components. Thus, diffusion of the formic acid gas will not adversely affect other components and can be carried out away from human presence. In some examples, relocating 702 the integrated circuit component is carried out by transporting the integrated circuit device component to the tooling (e.g., reflow or TCB tooling) used for joining integrated circuit device component to other components. In some variations, the fixture containing the integrated circuit device component is used to transport the component and is placed within the tool. As discussed above, the fixture is suitable for placement in the reflow furnace, box oven, or TCB bonding tool. For bonding, the integrated circuit device component may be mounted on another component, e.g., using a tacky adhesive.

The method of FIG. 7 also includes performing 704 a bonding process during which decomposition of the formate shell at a second target temperature removes an oxide layer on the one or more metal interconnect structures. In some examples, performing 704 the bonding process is carried out by performing a reflow process, TCB process, or other process in which heat and solder material are used to establish a mechanical and electrical bond between two integrated circuit device components. As part of the bonding process, the integrated circuit device components are placed or mounted and heated in excess of 230° C., depending on the type of bonding material and the type of bonding. At a temperature in the range of 180° C. to 230° C., the formate shell will begin to decompose. As the formate shell decomposes, it reduces any oxide layer present on the metal interconnect structures and is converted to water and carbon dioxide. In this way, the formate shell has the advantage of removing oxide from the metal surface like formic acid gas without the need for special adaptation of the bond tooling to handle formic acid gas.

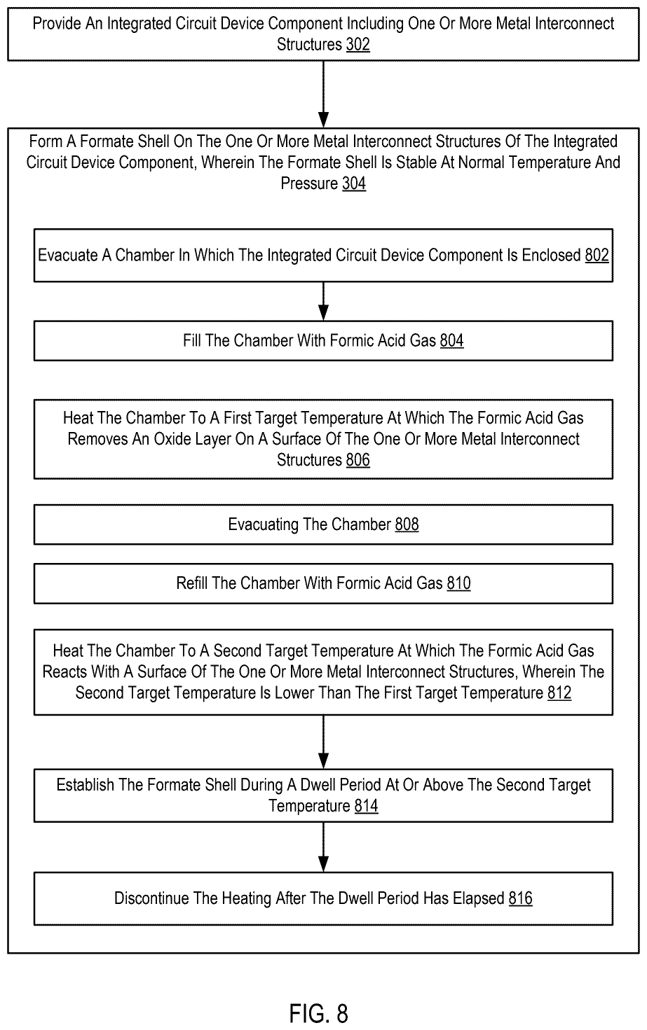

As discussed above, the application of a formate shell to metal interconnect structures addresses problems associated with the oxidation of those structures during storage or transport, as well the need for special tooling to handle formic acid gas during joining or bonding operations, among others. An alternative technique for creating the formate shell that also addresses these problems is now described with reference to FIG. 8, which sets for a flow chart for another example method for utilizing formate shells for metal structures on integrated circuit components in accordance with at least one embodiment of the present disclosure. In the method of FIG. 8, the oxide layer of the metal interconnect structures is removed prior to forming the formate shell, thus providing a metal formate shell.

The method of FIG. 8 extends the method of FIG. 3 in that forming 304 the formate shell on the one or more metal interconnect structures of the integrated circuit device component includes evacuating 802 a chamber in which an integrated circuit device component is enclosed, In some examples, evacuating 802 is carried out using a vacuum pump on a gas port on a chamber of a fixture, as discussed above.

In the method of FIG. 8, forming 304 the formate shell also includes filling 804 the chamber with formic acid gas. In some examples, filling 804 the chamber with formic acid gas is carried out by pumping a mixture of nitrogen and formic acid (CH₂O₂, having a structure H—C—O—O—H) into the chamber via a gas port. In a particular implementation, the resulting gas pumped into the chamber is approximately 5% saturated with formic acid.

In the method of FIG. 8, forming 304 the formate shell also includes heating 806 the chamber to a first target temperature at which the formic acid gas removes an oxide layer on a surface of the one or more metal interconnect structures. In some examples, heating 806 the chamber to a first target temperature at which the formic acid gas removes an oxide layer is carried out by heating the chamber to a temperature in the range of at least approximately 180° C. At and above this temperature, the formate shell will decompose and reduce any oxide layer on the metal interconnect structures. The redox reaction converts the formate and oxygen of the metal oxide to water and carbon dioxide, leaving a pure metal surface on the metal interconnect structures. It will be appreciated that, for some metals, the temperature at which the formate reduces the oxide may be high or lower.

In the method of FIG. 8, forming 304 the formate shell also includes evacuating 808 the chamber. As previously discussed, the chamber can be evacuated by pulling a vacuum on the gas port of the chamber.

In the method of FIG. 8, forming 304 the formate shell also includes refilling 810 the chamber with formic acid gas by, for example, pumping a mixture of nitrogen and formic acid (CH₂O₂, having a structure H—C—O—O—H) into the chamber via a gas port.

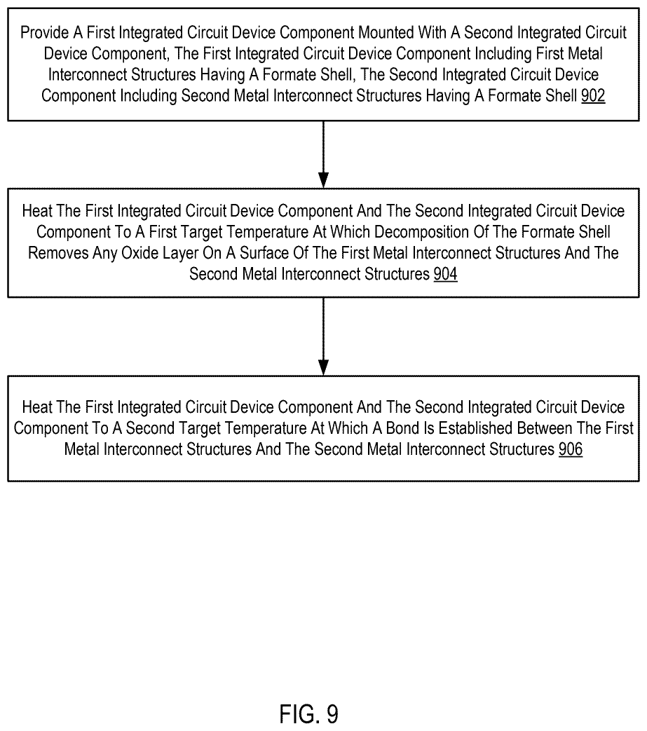

In the method of FIG. 9, forming 304 the formate shell also includes heating 812 the chamber to a second target temperature at which the formic acid gas reacts with a surface of the one or more metal interconnect structures, wherein the second target temperature is lower than the first target temperature. In some examples, heating 812 the chamber to a second target temperature at which the formic acid gas reacts with a surface of the one or more metal interconnect structures is carried out by heating the fixture in a conventional box oven or belt furnace and controlling the heat applied to the fixture. During a ramp up period, the temperature within the chamber is increased to a target temperature at which the formic acid gas will react with the metal or metal oxide of the metal interconnect structures. In various implementations, the target temperature may be within a range of 130° C. to 180° C.; however, it will be appreciated that the target temperature for creation of the formate shell will depend on the type of metal of the metal interconnect. Once the target temperature is reached, the formic acid will begin absorbing onto the metal or metal oxide of the metal interconnect structures.

In the method of FIG. 8, forming 304 the formate shell also includes establishing 814 the formate shell during a dwell period at or above the target temperature In some examples, establishing 814 the formate shell during a dwell period at or above the second target temperature is carried out by maintaining the temperature within the chamber at or above the target temperature but below a maximum peak temperature at which reduction of any oxide layer on the metal interconnect structures would occur and/or decomposition of the formate shell would occur. It will be appreciated that the maximum peak temperature at which reduction of any oxide layer on the metal interconnect structures would occur depends on the type of metal and can be determined from physical chemistry reference materials. The dwell period is an amount of time during which the formic acid absorbs onto the metal interconnect structures via a chemisorption bond, thus established a metal formate shell that completely covers any exposed metal of the metal interconnect structures.

In the method of FIG. 8, forming 304 the formate shell also includes discontinuing 816 the heating after the dwell period has elapsed. In some examples, discontinuing 816 the heating after the dwell period has elapsed is carried out by removing the fixture from the oven or furnace, or by discontinuing the heat applied by the oven or furnace. In contrast to techniques that use a special formic acid reflow tool, where heating of the components continues until the oxide is reduced and reflow occurs, techniques in accordance with the present disclosure discontinue heating of the integrated circuit device component once the formate shell has been established during the dwell period. After the dwell period is over, the heating is discontinued and the component can be removed from the fixture after removal or dissipation of the remaining formic acid gas within the chamber. Alternatively, the formic acid gas can be evacuated, thus conditioning the fixture for transport to a reflow oven, TCB tool, or other bonding facility. The resulting formate shell is stable, and the integrated circuit device component is prepared for exposure to air during storage or transport without risk of oxidation or further oxidation of the metal interconnect structures.

Once the formate shell has been created on the metal interconnect structures, the chamber can be evacuated and backfilled with nitrogen gas, as discussed above with reference to FIG. 5; the integrated circuit device component can be deposited in a storage container as discussed above with reference to FIG. 6; and/or the integrated circuit device component can be relocated to a bonding tool where the integrated circuit device can be joined to another integrated circuit device component as discussed above with reference to FIG. 7.

As mentioned above, during the bonding process the formate shell provides the benefits of formic acid in reducing oxides on the metal interconnects while obviating the need for special tooling to handle formic acid gas during reflow or TCB. For further explanation, FIG. 9 sets forth a flow chart of another example method of utilizing formate shells for metal structures on integrated circuit components. Specifically, FIG. 9 pertains to attaching two integrated circuit device components, such as the integrated circuit device component(s) discussed above with reference to FIGS. 1A, 1B, 2A, and 2B. The method of FIG. 9 includes providing 902 a first integrated circuit device component mounted with a second integrated circuit device component, the first integrated circuit device component including first metal interconnect structures having a formate shell, the second integrated circuit device component including second metal interconnect structures having a formate shell. In some examples, the providing 902 a first integrated circuit device component mounted with a second integrated circuit device component is carried out by placement of the components in a bonding fixture. In various examples, the first integrated circuit device component and the second integrated circuit device component are each one of a semiconductor die, a semiconductor module, a surface mount device, a substrate, an interposer, a wafer, a socket, and a connector. In some examples, the first metal interconnect structures and the second metal interconnect structures include at least one of solder structures, pillars, leads, and pads. Mounting of the components can include placing the first integrated circuit device component on the second integrated circuit device component, mating the first integrated circuit device component on the second integrated circuit device component, or other forms of coupling for the purpose of establishing a mechanical and electrical bond between the components. In some examples, a tacky adhesive is applied to at least one component before mounting the first integrated circuit device component and the second integrated circuit device component.

The method of FIG. 9 also includes heating 904 the first integrated circuit device component and the second integrated circuit device component to a first target temperature at which decomposition of the formate shell removes any oxide layer on a surface of the first metal interconnect structures and the second metal interconnect structures. In some examples, heating 904 the first integrated circuit device component and the second integrated circuit device component to a first target temperature at which decomposition of the formate shell removes an oxide layer is carried out by heating the components to a temperature of at least approximately 180° C. At and above this temperature, the formate shell will decompose and reduce any oxide layer on the metal interconnect structures. The redox reaction converts the formate and oxygen of the metal oxide to water and carbon dioxide, leaving a pure metal surface on the metal interconnect structures. It will be appreciated that, for some metals, the temperature at which the formate reduces the oxide may be high or lower. In various implementations, this first stage of heating can occur in a conventional box oven, belt furnace, reflow tool, or TCB tool, for example.

The method of FIG. 9 also includes heating 906 the first integrated circuit device component and the second integrated circuit device component to a second target temperature at which a bond is established between the first metal interconnect structures and the second metal interconnect structures. In some examples, heating 906 the first integrated circuit device component and the second integrated circuit device component to the second target temperature is carried out by heating the components to a temperature at which solder reflow or thermal compression bonding occurs. For example, the second target temperature may be 230° C. and above. This second stage of heating occurs in the same heating tool as the first stage of heating and without removing the integrated circuit device components from the fixture.

In view of the foregoing, it will be appreciated that a number of advantages are realized by utilizing formate shells for the preservation of metal components as well for their oxide reducing capabilities during thermal processes such as solder reflow. Formic acid bonds with metal or metal oxide to create the formate shell, which is then allowed to cool. These bonds of the formate shell are stable bonds and do not create an exposed metal surface that can react with oxygen during storage or transport. In subsequent bonding processes, when the formate shell is exposed to the thermal processes of bonding, the formate shell will reduce any oxide layers that are present on the metal interconnects. Decomposition of the formate shell does not yield any formic gas. Thus, the bonding tool does not require special adaptation to handle formic gas or safeguard against human exposure to it. Further, because the formate shell is stable and prevents oxidation, the formate shell can be used to extend the shelf-life of these components.

An embodiment is directed to an apparatus configured with a formate shell. The apparatus includes an integrated circuit device component including one or more metal interconnect structures. The apparatus also includes a formate shell on each of the one or more metal interconnect structures. In some examples, the formate shell includes a chemisorption bond between metal of the one or more metal interconnect structures and formate molecules. The formate shell is stable at normal temperature and pressure. In various examples, the formate shell is composed of a metal formate or metal oxide formate. In various examples, the integrated circuit device component is one of a semiconductor die, a semiconductor module, a surface mount device, a substrate, an interposer, a wafer, a socket, and a connector. In some examples, the one or more metal interconnect structures include at least one of a solder structure, pillar, lead, and pad. In this manner, the formate shell protects the metal interconnect from oxidation, thus permitting the integrated circuit device component to be stored for long periods of time, or to be transported from one processing point to another, without adversely affecting a future electrical connection of the integrated circuit device component to another component. Further, when the integrated circuit device component is eventually joined with another component, decomposition of the formate shell due to heating will remove any oxidation present on the metal interconnect structures. Thus, oxidation removal via the formate reaction is fluxless and can be carried out in conventional tooling such as a reflow furnace or TCB tool without special adaptation or safeguards for utilizing formic acid gas.

A variation of the embodiment is directed to a method of creating a formate shell. The method includes providing an integrated circuit device component including one or more metal interconnect structures. The method also includes forming a formate shell on the one or more metal interconnect structures of the integrated circuit device component, where the formate shell is stable. Forming the formate shell does not reduce the metal oxide. In various examples, the formate shell is composed of a metal formate or metal oxide formate. In various examples, the integrated circuit device component is one of a semiconductor die, a semiconductor module, a surface mount device, a substrate, an interposer, a wafer, a socket, and a connector. In some examples, the one or more metal interconnect structures include at least one of a solder structure, pillar, lead, and pad. In some examples, the metal interconnect structures are composed of one of copper, gold, nickel, and tin. In this manner, creation of the formate shell can be performed apart from the bonding tool and prior to placement in the bonding tool. Decomposition of the formate shell due to heating will remove any oxidation present on the metal interconnect structures. Thus, oxidation removal via the formate reaction is fluxless and can be carried out in conventional tooling such as a reflow furnace or TCB tool without special adaptation or safeguards for utilizing formic acid gas.

In some examples, forming the formate shell on the one or more metal interconnect structures of the integrated circuit device component includes evacuating a chamber in which the integrated circuit device component is enclosed, filling the chamber with formic acid gas; heating the chamber to a target temperature at which the formic acid gas reacts with a surface of the one or more metal interconnect structures, establishing the formate shell during a dwell period at or above the target temperature, discontinuing the heating after the dwell period has elapsed. In some variations, the method also includes evacuating the formic acid from the chamber and backfilling the chamber with nitrogen gas.

In some examples, the method also includes depositing the integrated circuit device component in a storage container. In other variations, the method includes relocating the integrated circuit component to a tool for bonding the integrated circuit device component to another integrated circuit device component and performing a bonding process during which decomposition of the formate shell at a second target temperature removes an oxide layer on the one or more metal interconnect structures. In variations, the bonding process is at least one of a reflow process and a thermal compression bonding process. The bonds of the formate shell are stable bonds and do not create an exposed metal surface that can react with oxygen during storage or transport. Thus, in subsequent bonding processes, when the formate shell is exposed to the thermal processes of bonding, the formate shell will reduce any oxide layers that are present on the metal interconnects.

In some examples, forming the formate shell on the one or more metal interconnect structures of the integrated circuit device component includes evacuating a chamber in which an integrated circuit device component is enclosed, filling the chamber with formic acid gas, heating the chamber to a first target temperature at which the formic acid gas removes an oxide layer on a surface of the one or more metal interconnect structures and evacuating the chamber. The method also includes refilling the chamber with formic acid gas, heating the chamber to a second target temperature at which the formic acid gas reacts with a surface of the one or more metal interconnect structures, wherein the second target temperature is lower than the first target temperature, establishing the formate shell during a dwell period at or above the second target temperature, and discontinuing the heating after the dwell period has elapsed.

Another embodiment is directed to a method of joining two components having a formate shell. The method includes providing a first integrated circuit device component mounted with a second integrated circuit device component. The first integrated circuit device component includes first metal interconnect structures having a formate shell. The second integrated circuit device component includes second metal interconnect structures having a formate shell. The method also includes heating the first integrated circuit device component and the second integrated circuit device component to a first target temperature at which decomposition of the formate shell removes any oxide layer on a surface of the first metal interconnect structures and the second metal interconnect structures. The method also includes heating the first integrated circuit device component and the second integrated circuit device component to a second target temperature at which a bond is established between the first metal interconnect structures and the second metal interconnect structures. Decomposition of the formate shell due to heating will remove any oxidation present on the metal interconnect structures. Thus, oxidation removal via the formate reaction is fluxless and can be carried out in conventional tooling such as a reflow furnace or TCB tool without special adaptation or safeguards for utilizing formic acid gas.

Another embodiment is directed to a metal structure including an exposed surface and a formate shell covering the surface. The formate shell includes chemisorption bonds between metal oxide molecules at the surface and formate molecules adsorbed onto the metal oxide. The bond is stable. In this manner, the formate shell protects the metal interconnect from oxidation, thus permitting the integrated circuit device component to be stored for long periods of time, or to be transported from one processing point to another, without adversely affecting a future electrical connection of the integrated circuit device component to another component. Further, when the integrated circuit device component is eventually joined with another component, decomposition of the formate shell due to heating will remove any oxidation present on the metal interconnect structures.

Yet another embodiment is directed to an apparatus for creating a formate shell. The apparatus includes a portable fixture including a chamber in which one or more integrated circuit device components are received. The apparatus also includes a gas port of the chamber. The gas port being operable to fill the chamber with formic acid gas that, when the fixture is heated, creates a formate shell on metal interconnect structures of the one or more integrated circuit device components. In some examples, the chamber is configured to receive a JEDEC tray. In some examples, the fixture is configured for placement in one or more of a belt furnace, box oven, reflow tool, and thermal compression bonding tool.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus comprising:
an integrated circuit device component including one or more metal interconnect structures; and
a formate shell on each of the one or more metal interconnect structures.

2. The apparatus of claim 1, wherein the formate shell includes a chemisorption bond between metal of the one or more metal interconnect structures and formate molecules.

3. The apparatus of claim 1, wherein the formate shell is stable at normal temperature and pressure.

4. The apparatus of claim 1, wherein the formate shell is composed of a metal formate.

5. The apparatus of claim 1, wherein the formate shell is composed of a metal oxide formate.

6. The apparatus of claim 1, wherein the integrated circuit device component is one of a semiconductor die, a semiconductor module, a surface mount device, a substrate, an interposer, a wafer, a socket, and a connector.

7. The apparatus of claim 1, wherein the one or more metal interconnect structures include at least one of a solder structure, pillar, lead, and pad.

8. A method comprising:
providing an integrated circuit device component including one or more metal interconnect structures; and
forming a formate shell on the one or more metal interconnect structures of the integrated circuit device component, wherein the formate shell is stable at normal temperature and pressure.

9. The method of claim 8, wherein forming the formate shell on the one or more metal interconnect structures of the integrated circuit device component includes:
evacuating a chamber in which the integrated circuit device component is enclosed;
filling the chamber with formic acid gas;
heating the chamber to a target temperature at which the formic acid gas reacts with a surface of the one or more metal interconnect structures;
establishing the formate shell during a dwell period at or above the target temperature; and
discontinuing the heating after the dwell period has elapsed.

10. The method of claim 9 further comprising:
evacuating the formic acid from the chamber; and
backfilling the chamber with nitrogen gas.

11. The method of claim 8 further comprising:
depositing the integrated circuit device component in a storage container.

12. The method of claim 8 further comprising:
relocating the integrated circuit component to a tool for bonding the integrated circuit device component to another integrated circuit device component;
performing a bonding process during which decomposition of the formate shell at a second target temperature removes an oxide layer on the one or more metal interconnect structures.

13. The method of claim 12, wherein the bonding process is at least one of a reflow process and a thermal compression bonding process.

14. The method of claim 8, wherein the formate shell is composed of a metal formate.

15. The method of claim 8, wherein the formate shell is composed of a metal oxide formate.

16. The method of claim 15, wherein the forming the formate shell does not reduce the metal oxide.

17. The method of claim 8, wherein the one or more metal interconnect structures is composed of one of copper, gold, nickel, and tin.

18. The method of claim 8, wherein integrated circuit device component is one of a semiconductor die, a semiconductor module, a surface mount device, a substrate, an interposer, a wafer, a socket, and a connector.

19. The method of claim 8, wherein the one or more metal interconnect structures include at least one of a solder structure, pillar, lead, and pad.

20. The method of claim 8, wherein forming the formate shell on the one or more metal interconnect structures of the integrated circuit device component includes:
evacuating a chamber in which an integrated circuit device component is enclosed;
filling the chamber with formic acid gas;
heating the chamber to a first target temperature at which the formic acid gas removes an oxide layer on a surface of the one or more metal interconnect structures;
evacuating the chamber;
refilling the chamber with formic acid gas;
heating the chamber to a second target temperature at which the formic acid gas reacts with a surface of the one or more metal interconnect structures, wherein the second target temperature is lower than the first target temperature;
establishing the formate shell during a dwell period at or above the second target temperature; and
discontinuing the heating after the dwell period has elapsed.

21. A method comprising:
providing a first integrated circuit device component mounted with a second integrated circuit device component, the first integrated circuit device component including first metal interconnect structures having a formate shell, the second integrated circuit device component including second metal interconnect structures having a formate shell;
heating the first integrated circuit device component and the second integrated circuit device component to a first target temperature at which decomposition of the formate shell removes any oxide layer on a surface of the first metal interconnect structures and the second metal interconnect structures; and
heating the first integrated circuit device component and the second integrated circuit device component to a second target temperature at which a bond is established between the first metal interconnect structures and the second metal interconnect structures.

22. A device comprising:
a metal structure including an exposed surface; and
a formate shell covering the surface, the formate shell including chemisorption bonds between metal oxide molecules at the surface and formate molecules adsorbed onto the metal oxide, wherein the bond is stable.

23. An apparatus for creating a formate shell, the apparatus comprising:
a portable fixture including a chamber in which one or more integrated circuit device components are received; and
a gas port of the chamber, the gas port being operable to fill the chamber with formic acid gas that, when the fixture is heated, creates a formate shell on metal interconnect structures of the one or more integrated circuit device components.

24. The apparatus of claim 23, wherein the chamber is configured to receive a JEDEC tray.

25. The apparatus of claim 23, wherein the fixture is configured for placement in one or more of a belt furnace, box oven, reflow tool, and thermal compression bonding tool.
